(19) United States
(12) Patent Application Publication
(10) Pub. No.: US 2005/0092519 A1
(43) Pub. Date: May 5, 2005

(54) Partially flexible circuit board

(76) Inventors: John K. Beauchamp, Nongkham Sriracha Chonburi (TH); Sakchai Paengkam, Sriracha Chonburi (TH)

Correspondence Address: AUZVILLE JACKSON, JR., 8652 RIO GRANDE ROAD, RICHMOND, VA, 23229, US

(21) Appl. No.: 10/701,974

(22) Filed: Nov. 5, 2003

(51) Int. Cl. H05K 1/03; H05K 3/46

(52) U.S. Cl. 174/255; 174/254; 29/846

(57) ABSTRACT

A partially flexible circuit board and a method of manufacturing the same. The partially flexible circuit board of the present invention comprises: laminated alternating layers of prepreg and conductive printed circuitry with apertures in one or more of the prepreg layers in those areas that are required to undergo limited flexing. Fabrication is accomplished by removal of the prepreg in the aperture area of at least one of the prepreg layers; filling of the aperture with a suitable heat resistant and non-adhesive filler prior to lamination; laminating additional prepreg and conductive printed circuit layers prepared for revealing the aperture, subsequent to lamination; cutting slots at the edges of the circuit board that communicate with the apertures to permit flexing across the width thereof without interference with the encompassed circuitry; and removing the filler and any residual prepreg from the aperture to leave the aperture in the prepreg and conductive foil at the desired locations(s).

### FIELD OF THE INVENTION

The present invention relates to circuit boards and their manufacture and more particularly to circuit boards that are neither rigid nor flexible in the conventionally accepted sense, but rather semi or partially flexible and thus can be used in applications that are unsuited to rigid circuit boards, but that do not require the flexibility of relatively high cost flexible circuit boards.

### BACKGROUND OF THE INVENTION

In the prior art, there are basically two distinct classes of circuit boards, so-called rigid circuit boards and so-called flexible circuit boards. The former are those conventionally used in the manufacture of electronic devices such as cellular phones, televisions, radios etc. Flexible circuit boards are those used in applications where the “flat” circuitry must undergo relatively high levels of repetitive flexing. A common such application familiar to most users would be the flexible circuit boards used in computer printers where the printed circuit used to feed electrical pulses to the printer head must travel with the head resulting in a repetitive flexing of the board. Such boards are relatively expensive to manufacture due to the requirement that they be capable of undergoing somewhere on the order of several hundred thousand “flexes” without disruption of the contained circuitry. While rigid circuit boards use relatively inexpensive fiber glass prepreg materials as the prepreg material, flexible circuit boards use significantly more expensive prepreg materials.

There are many applications for printed circuitry that require a circuit board to flex only a relatively limited number of times, perhaps on the order of one to as many as several times during, for example fabrication operations. An example of such an application would be in the case where it would be desirable, perhaps due to the size and/or shape of a device case, to have a circuit that requires a board of such a size that it must be comprised of a pair of circuit boards positioned at right angles to one another. Current manufacturing techniques would satisfy this need by producing two separate rigid boards that are joined by soldered or otherwise connected tines from each of the individual boards at the right angle bend. Such manufacturing operations are relatively expensive and labor intensive, but the application will not support nor does it require the capabilities of the even more expensive flexible circuit boards. The circuit board of the present invention allows for limited flexing for a limited number of times and permits the fabrication and installation of a single partially or semi flexible board in such an application.

Thus, the availability of a relatively inexpensive hybrid rigid/flexible circuit board that is sufficiently flexible as to permit flexing once or twice, for example, during the fabrication operation, but never be flexed again, would be highly useful to the electronic components industry.

### OBJECTS OF THE INVENTION

It is therefore an object of the present invention to provide a partially or semi-flexible printed circuit board that can undergo a relatively limited number of flexes without breaking.

It is another object of the present invention to provide such a circuit board whose cost is relatively that of a conventional rigid circuit board, i.e. significantly less than that of a conventional flexible circuit board.

### SUMMARY OF THE INVENTION

According to the present invention, there are provided a partially flexible circuit board and a method of manufacturing the same. The partially flexible circuit board of the present invention comprises: laminated alternating layers of prepreg and conductive printed circuitry with apertures in one or more of the prepreg layers in those areas that are required to undergo limited flexing. Manufacture of such partially flexible circuit boards is accomplished by removal of the prepreg in the aperture area of at least one of the prepreg layers; filling of the aperture with a suitable removable filler prior to lamination; laminating additional prepreg and conductive foil layers prepared for revealing the aperture and subsequent to lamination removal of the filler to leave the apertures in the prepreg and conductive foil layers at the desired locations(s) as well as the cutting of slots at the edges of the circuit board that communicate with the apertures to permit flexing across the width thereof without interference with the encompassed circuitry.

### DESCRIPTION OF THE DRAWINGS

FIG. 1 is a schematic cross-sectional depiction of one embodiment of the circuit board of the present invention.

FIG. 2 is a schematic cross-sectional depiction of another embodiment of the circuit board of the present invention.

FIG. 3 is a schematic cross-sectional depiction of yet another embodiment of the circuit board of the present invention.

FIG. 4 is a schematic exploded depiction showing the method of assembly of the circuit board of the present invention.

FIG. 5 is a bottom plan view of a three part partially flexible circuit board in accordance with the present invention.

FIG. 6 is a perspective, schematic, exploded view showing the method of fabrication of partially flexible circuit boards in accordance with the method of the present invention.

FIG. 7 is a schematic depiction of the circuit board of FIG. 5 in a flexed or bent position.

### DETAILED DESCRIPTION

The partially or semi flexible circuit boards of the present invention are manufactured using many of the conventional and essential process steps and materials used for the manufacture of rigid circuit boards, all of which are well known to those skilled in the circuit board fabrication/manufacture arts. Because of this fact, many of the process steps, details of the finished board and materials used in the processes and products of the present invention are described only in general terms in this application, it being well within the skill of the art to prepare the products of the present invention in accordance with the methods of the present invention using the prior art methods and materials once the process variation techniques described herein are known. Such is the case, for example, where plated through holes are not represented in the many of the attached schematic Figures. The presence of these features and their introduction into the product are well known to the skilled artisan and their incorporation into the novel partially flexible circuit boards of the present invention is well within the skill of the art. Similarly, lamination and photoetching techniques and the like conventionally used in the fabrication of circuit boards are not described in, any detail as these are common in the fabrication of rigid circuit boards. It should also be noted that in the various Figures attached hereto, the relative thickness of the metallic foil layers and patterns is exaggerated for purposes of clarity, it being understood that the foil layers are significantly thinner than the prepreg layers as is the case in the conventional manufacture of printed circuit boards.

Referring now to FIG. 1, the simplest embodiment of the novel circuit boards of the present invention is a single sided board 10 comprising a prepreg layer 12 having a single discontinuous conductive foil layer, a pattern, (represented by areas 14 and 22 in FIG. 1) thereon formed using conventional fabrication techniques, i.e. through the lamination of conductive foil to prepreg layer 12 and photo etching the conductive foil to provide areas 14 and 22, the pattern, in the appropriate locations. Cut out area 16, formed in second prepreg layer 13 as described below, allows essentially rigid circuit board portions 18 and 20 to limitedly flex relative to one another. In this configuration, conductive foil pattern 22 and section 24 of prepreg layer 12 can flex allowing rigid portions 18 and 20 to flex relative to one another.

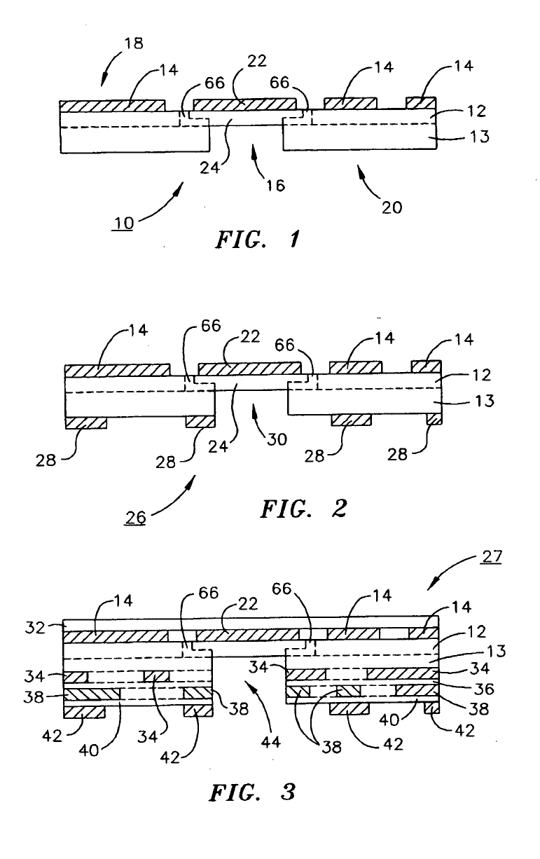

FIG. 2 depicts a schematic cross-section of a second embodiment of the partially flexible circuit board of the present invention. The embodiment depicted in FIG. 2 shows a double sided partially flexible circuit board 26 comprising a prepreg layer 12 to which are laminated foil patterns 14 and 22 and apertured prepreg 13 to which a second array of foil patterns 28 have been applied by conventional lamination and photo-etching techniques. Aperture 30 in prepreg layer 13 is provided as described below. In this double sided configuration, partially flexible circuit board 26 can flex about portion 24 as described above in connection with the single sided configuration depicted in FIG. 1.

Referring now to FIG. 3, in this figure, there is schematically depicted a multi-layer partially flexible circuit board 27 of the present invention. As shown in this Figure, the multi-layer partially flexible circuit board 27 comprises a first prepreg layer 12 having conductive foil patterns 14 and 22 laminated thereon and second prepreg layer 13 laminated to the “underside” (that opposite the side to which foil patterns 14 and 22 are laminated) thereof which is the structure of the double sided circuit board depicted in FIG. 2. Additional layers are then laminated to the structure of FIG. 2 as follows: over the top of foil patterns 14 and 22 is laminated another prepreg layer 32; to prepreg layer 13 are laminated foil patterns 34 formed in the conventional fashion by lamination and photo-etching; another prepreg layer 36 is laminated over conductive foil patterns 34; additional conductive foil patterns 38 are laminated and formed on prepreg layer 36; yet another prepreg layer 40 is applied over conductive foil patterns 38; and finally, conductive foil patterns 42 are applied over prepreg layer 40 to complete the structure. As will be apparent to the skilled artisan, this type of construction/fabrication can continue virtually indefinitely. Aperture 44 in the bottom of circuit board 27 provides the point about which partial flexing can occur. Application of the conductive foil layers/areal portions described in this configuration is, of course, accomplished using conventional lamination and photo-etching techniques as are well known in the circuit board manufacturing arts.

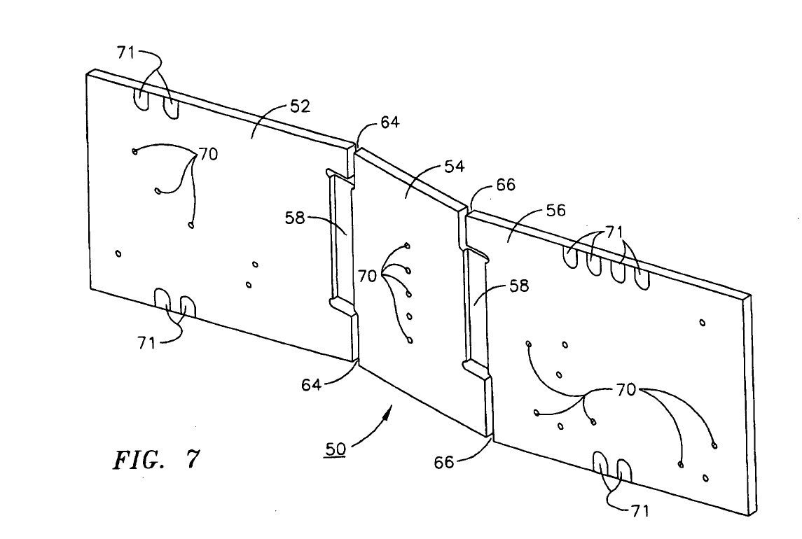

FIG. 5 depicts a bottom plan view of a partially flexible circuit board 50 fabricated in accordance with the present invention. As shown in this Figure, partially flexible circuit board 50 comprises three portions 52, 54 and 56, each of which comprises essentially a rigid, multi-layer circuit board fabricated as described above. The apertures or recesses 58 in circuit board 50 are as shown for aperture or recess 44 in FIG. 3. Apertures or recesses 58 allow the three portions to flex about these recesses as shown in FIG. 7. As will be apparent to the skilled artisan, although apertures 16, 34 and 44 depicted in FIGS. 1-3 as well as apertures 58 depicted in FIG. 5 will permit flexing in those areas of circuit boards 16, 30,27 and 50 in the regions where they are located, there are areas along the edges such as 60 and 62 in FIG. 5 where allowance must be made to permit flexing in areas outside the boundaries of apertures 58. To provide such allowance, slots 64 and 66 are routed through the total thickness of those portions of partially flexible circuit board 50 outside of the area of apertures 58, but adjoining apertures 58 during fabrication. With the presence of these slots, partially flexible circuit board 50 possesses limited flexibility at each of the “joints” formed by apertures 58 and slots 64 and 66. Electrical connection between portions 52, 54 and 56 is accomplished by the presence of conductive foil patterns 22 “embedded” or laminated with or between one or more prepreg layers 12 and/or 32 as depicted in FIGS. 1 and 3. Plated through holes 70 are provided in the conventional fashion as are conventional contacts 71, both of which allow for connection/installation of electronic components in the manner well known in the electronic fabrication arts.

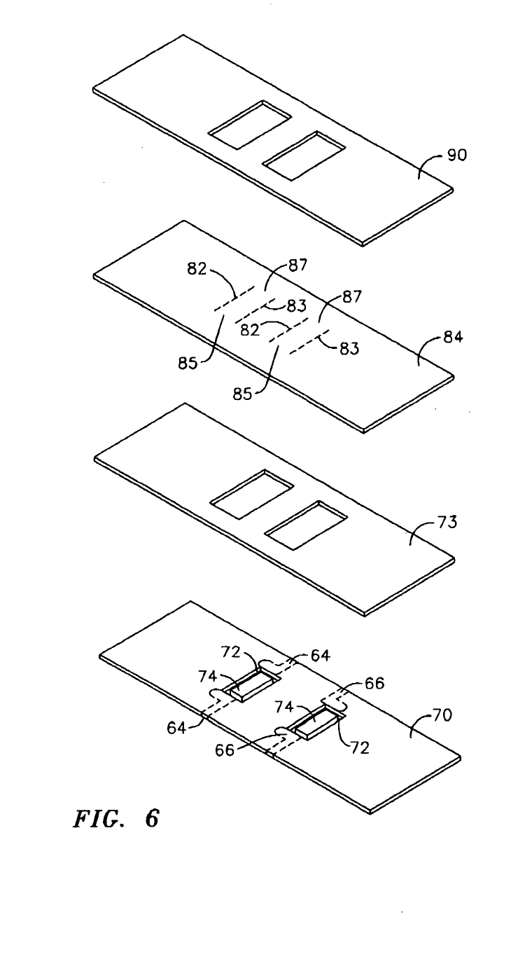

A better understanding of the structure and fabrication of the partially flexible circuit boards of the present invention can be gathered from an understanding of the fabrication method used to produce them. This is best illustrated by reference to FIG. 6 that shows a partial, schematic, inverted, exploded cross-sectional view of a partially flexible circuit board 62 in accordance with the present invention. As shown in this Figure, partially flexible circuit board 62 comprises a core of a prepreg layer 64 having two conductive foil layers 66 and 68 laminated thereto. Another prepreg layer 70 is laminated over the top of conductive foil layer 66. Prior to lamination of prepreg layer 70 to conductive foil layer 66 an aperture 72 is cut in prepreg layer 70 at the appropriate location and of the appropriate size to permit flexing of partially flexible circuit board 62 about the area of aperture 72 after lamination into the circuit board structure. Also prior to lamination of prepreg layer 70 to conductive foil layer 66 a filler block 74 of silicone or some similar high temperature resistant and non-adhesive material is inserted into aperture 72 to support the overlaid conductive foil layer 73 during the lamination and photo-etching processes as well as subsequently applied additional prepreg layers. Subsequently applied additional prepreg and conductive foil patterns are added in similar fashion with those portions of the additional foil layers that lie within the area of aperture 72 being removed during photoetching and the edges 76 and 78 of areas 80 and 82 of subsequently applied prepreg layers 84 and 86 perforated or cut along lines 82 and 83 such that in a subsequent routing operation to provide, for example, slot 66, the unscored, perforated or cut ends 85 and 87 are cut and areas 80 and 82 easily removed from the structure along with filler 74 to provide an aperture as shown at 58 in FIG. 5.

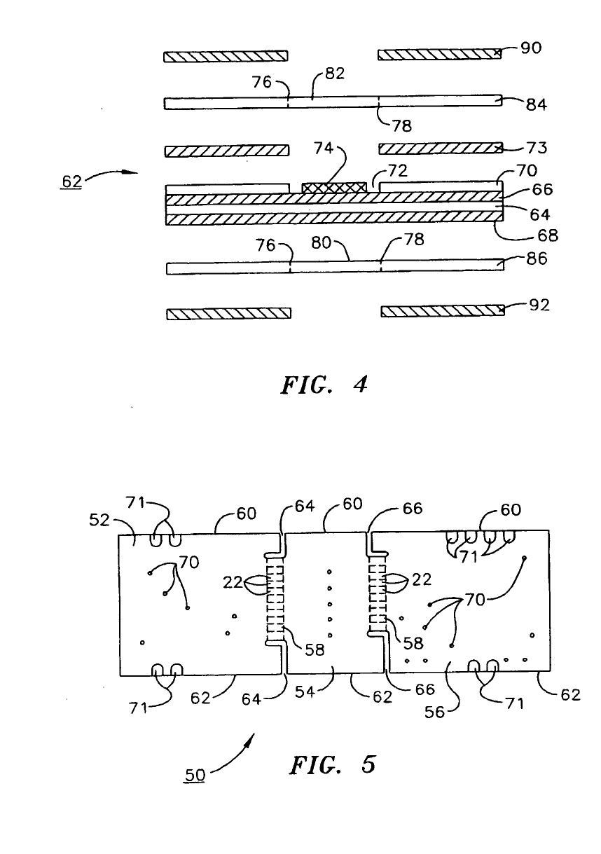

FIG. 6 depicts an exploded perspective view of a circuit board assembly similar to that depicted in FIG. 4, except that a pair of apertures 72 are provided therein.

In the final routing step of the fabrication process of the present invention, slots 64 and 66 are routed from the outside edges (60 and 62 in FIG. 5) of the partially flexible circuit board. Such routing removes the full thickness of circuit board 50, provides the slots 64 and 66 necessary to permit flexing of circuit board 50 and also allows for removal of areas of prepreg layers such as 80 and 82 as depicted in FIGS. 4 and 6 as well as the previously inserted filler. To provide proper flexing, it is important that those portions of slots 64 and 66 at right angles to edges 60 and 62 be coaxial.

Thus what have been described are: 1) a partially flexible circuit board comprising at least two rigid circuit board portions comprising a core of at least one connective conductive foil pattern laminated to one or more prepreg members and optionally additional alternating layers of prepreg and conductive foil on one or both surfaces of the core, the rigid circuit board portions being joined at a joint defined by the core and an aperture in the rigid circuit board portions on one or both surfaces in the area of the joint; and 2) a method for the fabrication of a partially flexible circuit board comprising: a) forming a circuit board core having longitudinal edges and comprising at least one conductive foil layer laminated to at least one prepreg layer, b) laminating to the at least one conductive foil layer a first prepreg layer having an aperture therein in the area of an intended joint, c) inserting a heat resistant, non-adhesive filler member into the aperture, d) laminating to the first prepreg layer a first layer of conductive foil, e) forming a conductive pattern in the first layer of conductive foil, at least a portion of the pattern including a vacant area that registers with the aperture; f) further laminating alternating layers of: A) prepreg having score lines that define opposing edges of areas that register with the aperture upon lamination and are perpendicular to the longitudinal edges, and B) conductive foil; g) forming a conductive pattern in each of the alternating layers of conductive foil which pattern includes a vacant area that registers with the aperture when laminated to the core until a desired number of layers is achieved; routing slots from the longitudinal edges to and along opposing extremities of the aperture and removing the heat resistant, non-adhesive filler and any areas of prepreg from the aperture.

As the invention has been described, it will be apparent to those skilled in the art that the same may be varied in many ways without departing from the spirit and scope of the invention. Any and all such modifications are intended to be included within the scope of the appended claims.

1) A partially flexible printed circuit board comprising:
a) at least two rigid circuit board portions each comprising;
i) a core having opposing planar surfaces and comprising at least one conductive foil pattern laminated to one or more prepreg layers; and
ii) additional alternating layers of prepreg and conductive foil patterns on one or both planar surfaces of the core;
b) the rigid circuit board portions being joined by a joint comprising the core that includes a connective pattern of conductive foil and registered apertures in the additional alternating prepreg and conductive foil patterns.

2) The partially flexible printed circuit board of claim 1 comprising a plurality of rigid circuit board portions joined together at joints between neighboring rigid circuit board portions.

3) A method for the fabrication of a partially flexible circuit board comprising:
a) forming a circuit board core having longitudinal edges and comprising at least one conductive foil pattern laminated to at least one prepreg layer;
b) laminating t the at least one conductive foil pattern a first prepreg layer having an aperture therein in an area of an intended joint;
c) inserting a heat resistant, non-adhesive filler member into the aperture,
d) laminating to the first prepreg layer a first layer of conductive foil;
e) forming a conductive pattern in the first conductive foil layer, at least a portion of the pattern including a vacant area that registers with the aperture;
f) further laminating additional alternating layers of:
A) prepreg having score lines that define opposing edges of areas that register with the aperture upon lamination and are perpendicular to the longitudinal edges; and
B) conductive foil;
g) forming a conductive pattern in each of the alternating layers of conductive foil which pattern includes a vacant area that registers with the aperture when laminated to the core until a desired number of layers is achieved;
h) routing slots from the longitudinal edges to and along opposing extremities of the aperture that do not include score lines; and
i) removing the heat resistant, non-adhesive filler and any areas of residual prepred from the aperture.

4) The method of claim 3 wherein the heat resistant, non-adhesive filler comprises a silicone filler.
